(19) United States
(12) Patent Application Publication
(10) Pub. No.: US 2023/0213699 A1
(43) Pub. Date: Jul. 6, 2023

(54) OPTICAL WAVEGUIDE PACKAGE AND LIGHT-EMITTING DEVICE

(71) Applicant: KYOCERA CORPORATION, Kyoto-shi, Kyoto (JP)

(72) Inventor: Yoshiaki ITAKURA, Aira-shi, Kagoshima (JP)

(73) Assignee: KYOCERA CORPORATION, Kyoto-shi, Kyoto (JP)

(21) Appl. No.: 17/927,656

(22) PCT Filed: May 18, 2021
(86) PCT No.: PCT/JP2021/018825

§ 371 Date: Nov. 23, 2022

(30) Foreign Application Priority Data
May 29, 2020 (JP) 2020-094753

(51) Int. Cl. G02B 6/12; G02B 6/125

(52) U.S. Cl. CPC G02B 6/12004; G02B 6/125

(57) ABSTRACT

An optical waveguide package includes a substrate including a first surface and a second surface opposite to the first surface, a cladding located on the second surface and including a third surface facing the second surface, a fourth surface opposite to the third surface, and an element-receiving portion with an opening in the fourth surface, a core located in the cladding and extending from the element-receiving portion, and a first metal member located in the element-receiving portion in a plan view as viewed in a direction toward the fourth surface and including an element mount. The first metal member is connected to a second metal member with a first via conductor extending through the substrate from the first surface to the second surface.

### TECHNICAL FIELD

The present disclosure relates to an optical waveguide package and a light-emitting device.

### BACKGROUND OF INVENTION

A known technique is described in, for example, Patent Literature 1.

### CITATION LIST

### Patent Literature

Patent Literature 1: Japanese Patent No. 4579868

### SUMMARY

In an aspect of the present disclosure, an optical waveguide package includes a substrate including a first surface and a second surface opposite to the first surface, a cladding located on the second surface and including a third surface facing the second surface, a fourth surface opposite to the third surface, and an element-receiving portion with an opening in the fourth surface, a core located in the cladding and extending from the element-receiving portion, and

a first metal member located in the element-receiving portion in a plan view as viewed in a direction toward the fourth surface and including an element mount. The first metal member is connected to a second metal member with a first via conductor extending through the substrate from the first surface to the second surface.

In another aspect of the present disclosure, a light-emitting device includes the optical waveguide package according to the above aspect, a light-emitting element connected to the first metal member, and a lens on an optical path of light emitted from the core.

### BRIEF DESCRIPTION OF THE DRAWINGS

The objects, features, and advantages of the present disclosure will become more apparent from the following detailed description and the drawings.

FIG. 1 is a cross-sectional view of a light-emitting device 1 including an optical waveguide package 2 according to a first embodiment.

FIG. 2 is a plan view of the light-emitting device 1.

FIG. 3 is a perspective view of the light-emitting device 1.

FIG. 4A is a cross-sectional view of a light-emitting device 1a according to a second embodiment.

FIG. 4B is a plan view of the light-emitting device 1a illustrating its internal structure.

FIG. 5A is a cross-sectional view of a light-emitting device 1b according to a fourth embodiment.

FIG. 5B is a bottom view of the light-emitting device 1b.

FIG. 6A is a cross-sectional view of a light-emitting device 1b with an example structure similar to the structure according to the fourth embodiment.

FIG. 6B is a bottom view of the light-emitting device 1b.

FIG. 7 is a partial cross-sectional view of a light-emitting device 1c according to a fifth embodiment.

FIG. 8A is a cross-sectional view of a light-emitting device 1d according to a sixth embodiment.

FIG. 8B is a plan view of the light-emitting device 1d without a lid 23.

FIG. 8C is a bottom view of the light-emitting device 1d.

FIG. 9A is a cross-sectional view of a light-emitting device 1e according to a seventh embodiment.

FIG. 9B is a plan view of the light-emitting device 1e without the lid 23.

FIG. 9C is a bottom view of the light-emitting device 1e.

FIG. 10A is a cross-sectional view of a light-emitting device 1f according to an eighth embodiment.

FIG. 10B is a plan view of the light-emitting device 1f without the lid 23.

FIG. 10C is a bottom view of the light-emitting device 1f.

FIG. 11A is a cross-sectional view of a light-emitting device 1g according to a ninth embodiment.

FIG. 11B is a plan view of the light-emitting device 1g without the lid 23.

FIG. 11C is a bottom view of the light-emitting device 1g.

FIG. 12A is a cross-sectional view of a light-emitting device 1h according to a tenth embodiment.

FIG. 12B is a plan view of the light-emitting device 1h without the lid 23.

FIG. 12C is a bottom view of the light-emitting device 1h.

FIG. 13 is a cross-sectional view of a light-emitting device 1i according to an eleventh embodiment.

### DESCRIPTION OF EMBODIMENTS

The structure that forms the basis of an optical waveguide package according to one or more embodiments of the present disclosure and a light-emitting device including the optical waveguide package includes an optical integrated circuit including a gas-barrier optical waveguide including a non gas-barrier core and a non gas-barrier cladding having a permeability coefficient for helium lower than or equal to 5×10⁻⁹ cm³(STP)mm/(cm²sec·cm·Hg) (25° C.) coated with a gas-barrier thin film, a gas-barrier cap, an optical element including a light receiver or a light emitter mounted on a first surface of the optical waveguide at a position to be optically coupled to the core, and a metal wiring member on the first surface of the waveguide and direct below the thin film to be electrically connected to the optical element on the first surface of the optical waveguide.

To mount the optical waveguide and the cap on the optical integrated circuit, the thin film on the first surface of the optical waveguide and on the metal wiring member and a second surface of the cap are joined together with a gas-barrier inorganic material layer in between, without an organic material layer, to achieve gas-barrier performance. A sealed airtight space is defined by the thin film on the optical waveguide and the gas-barrier members alone. The sealed airtight space accommodates one end of the core and the optical element.

An optical waveguide package and a light-emitting device according to one or more embodiments of the present disclosure will now be described with reference to the drawings. The figures referred to below are schematic diagrams illustrating main components of the optical waveguide package and the light-emitting device for ease of illustration. The optical waveguide package and the light-emitting device may include known components not illustrated in the figures, such as circuit boards, wire conductors, control ICs, or LSIs. In the embodiments described below, the same reference numerals denote the corresponding components and will not be described repeatedly.

### First Embodiment

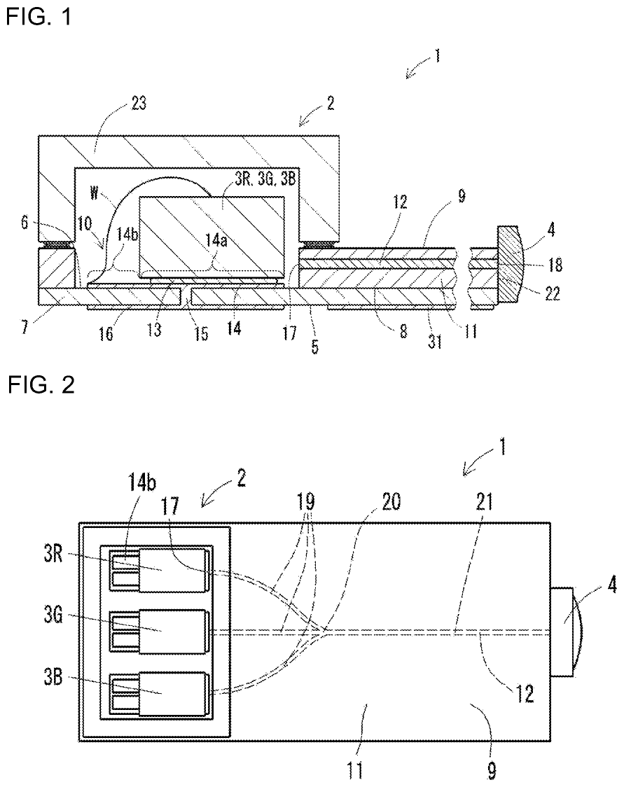

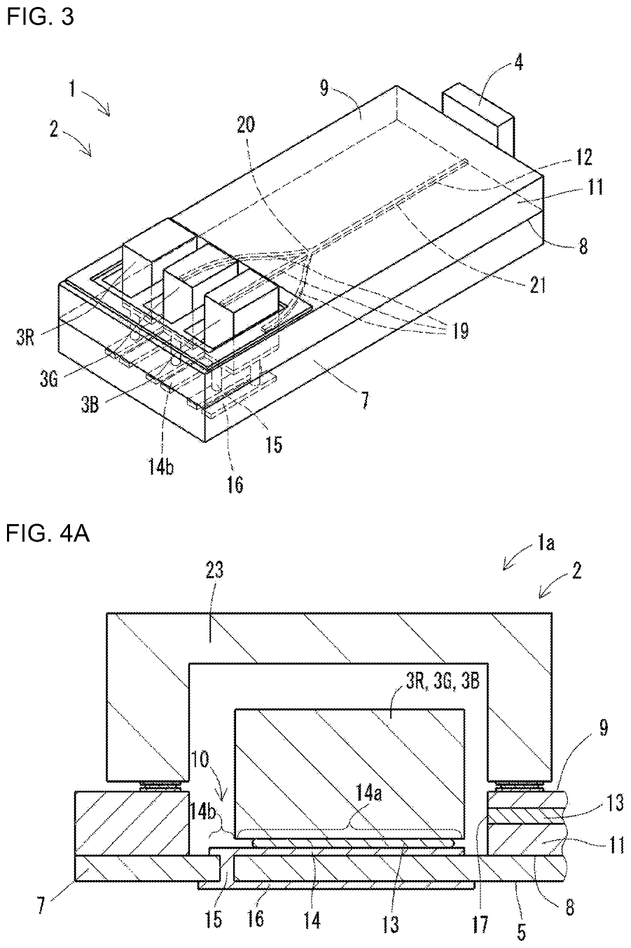

FIG. 1 is a cross-sectional view of a light-emitting device 1 including an optical waveguide package 2 according to a first embodiment. FIG. 2 is a plan view of the light-emitting device 1. FIG. 3 is a perspective view of the light-emitting device 1. In the present embodiment, the light-emitting device 1 includes the optical waveguide package 2, light-emitting elements 3R, 3G, and 3B corresponding to red, green, and blue light, and a condenser lens 4.

The optical waveguide package 2 includes a substrate 7 including a first surface 5 and a second surface 6 opposite to the first surface 5, a cladding 11 located on the second surface 6 and including a third surface 8 facing the second surface 6, a fourth surface 9 opposite to the third surface 8, and an element-receiving portion 10 with openings in the fourth surface 9, a core 12 located in the cladding 11 and extending from the element-receiving portion 10, and first metal members 14 located in the element-receiving portion 10 in a plan view as viewed in a direction toward the fourth surface 9 and each including an element mount 13.

The substrate 7 may be a ceramic board including dielectric layers made of a ceramic material. Examples of the ceramic material used for the ceramic board include sintered aluminum oxide, sintered mullite, sintered silicon carbide, sintered aluminum nitride, and sintered glass ceramic. For the substrate 7 being a ceramic board, the dielectric layers include conductors such as connection pads, internal wiring conductors, and external connection terminals for electrical connection between the light-emitting elements 3R, 3G, and 3B and an external circuit.

The substrate 7 may be an organic board including dielectric layers made of an organic material. The organic board may be a printed board, a build-up board, or a flexible board. Examples of the organic material used for the organic board include an epoxy resin, a polyimide resin, a polyester resin, an acrylic resin, a phenolic resin, and a fluororesin.

The core 12 is located in the cladding 11. The core 12 and the cladding 11 form an optical waveguide. Both the core 12 and the cladding 11 may be glass or a resin. In some embodiments, one of the core 12 and the cladding 11 may be glass, and the other may be a resin. In this case, the core 12 and the cladding 11 have different refractive indexes, or specifically, the core 12 has a higher refractive index than the cladding 11. The difference in the refractive index causes total internal reflection of light. More specifically, a material with a higher refractive index is used for an optical path, which is then surrounded by a material with a lower refractive index. This structure confines and carries light in the core 12 with the higher refractive index.

The core 12 includes multiple incident end faces 17 and one emission end face 18. The core 12 defines, between the incident end faces 17 and the emission end face 18, a merging path including multiple branching paths 19, a merging portion 20, and a joined path 21. The branching paths 19 include the corresponding incident end faces 17 at one end. The merging portion 20 merges the branching paths 19 together. The joined path 21 includes the emission end face 18 at one end.

The condenser lens 4 faces the emission end face 18 of the core 12 and a side surface 22 of the substrate 7 adjacent to the emission end face 18. The condenser lens 4 may be, for example, a lens such as a SELFOC (registered trademark) lens or a rod lens, or an optical element such as a diffraction grating. The condenser lens 4 has an optical axis aligned with the central axis of the emission end face 18. The condenser lens 4, which is an optical member, may face at least a portion of the emission end face 18 of the core 12 and the side surface 22 of the substrate 7 adjacent to the emission end face 18. In other words, the condenser lens 4 may be on an optical path of the light emitted from the core 12.

Red (R) light, green (G) light, and blue (B) light emitted from the respective light-emitting elements 3R, 3G, and 3B enter the respective branching paths 19 through the incident end faces 17 and pass through the merging portion 20 and the joined path 21 to the condenser lens 4, through which the light is condensed and emitted.

The condenser lens 4 is, for example, a plano-convex lens with a flat incident surface and a convex emission surface. The optical waveguide package 2 includes the optical waveguide, the light-emitting elements 3R, 3G, and 3B, and the condenser lens 4 assembled together to align the optical axis of each branching path 19 with the center of a light emitter in the corresponding light-emitting element 3R, 3G, or 3B.

The cladding 11 includes recesses each defined by a bottom surface and inner wall surfaces surrounding the bottom surface. The recesses serve as the element-receiving portion 10. The recesses may extend from the fourth surface 9 to the third surface 8. A lid 23 is placed to cover the element-receiving portion 10. The element-receiving portion 10 extends from the fourth surface 9 to the third surface 8. The lid 23 is a component recessed downward and is sized to cover the element-receiving portion 10 and can receive wiring members W used for wire bonding. The lid 23 may be formed by wet etching, dry etching, sandblasting, or another method.

First metal members 14 each are connected to a second metal member 16 with a first via conductor 15 extending through the substrate 7 from the first surface 5 to the second surface 6 of the substrate 7. This structure allows connection to a power supply through secondary mounting and eliminates complicated conductor stacking between the lid 23 and the cladding 11 as well as extra processes for such complicated conductor stacking. This structure also achieves electrical connection while providing sufficient airtightness and electrical insulation. The optical waveguide package 2 includes fewer junctions and leads and is thus smaller.

### Second Embodiment

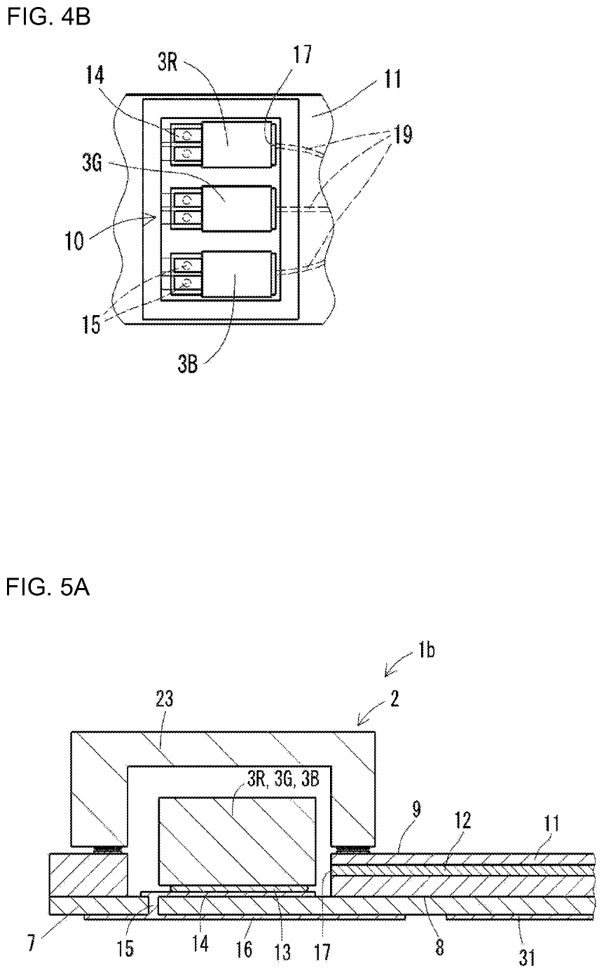

FIG. 4A is a cross-sectional view of a light-emitting device la according to a second embodiment. FIG. 4B is a plan view of the light-emitting device la illustrating its internal structure. The same reference numerals denote the components corresponding to those in the above embodiment and will not be described repeatedly. In the light-emitting device 1a according to the present embodiment, each first metal member 14 includes a first area 14a, which is the element mount 13, and a second area 14b other than the first area 14a. Each first via conductor 15 is in contact with the corresponding first metal member 14 on the second area 14b.

The light-emitting elements 3R, 3G, and 3B have smaller variations in the height and the degree of tilt when the first via conductors 15 are located to avoid the first areas 14a, which are the element mounts 13, or more specifically, when the first via conductors 15 are located on the corresponding second areas 14b. A portion including a via conductor may be surrounded by a portion protruding or recessed from the surface of the substrate. However, the first via conductors 15 located to avoid the element mounts 13 allows highly accurate positioning of the light-emitting elements 3R, 3G, and 3B during mounting. Thus, the light-emitting elements 3R, 3G, and 3B each have an optical axis positioned more accurately.

### Third Embodiment

The first metal members 14 in an embodiment are located in the openings alone in a plan view as viewed in a direction toward the fourth surface 9. This structure is used for the reasons below. When the first metal members 14 extend onto the third surface 8 between the cladding 11 and the substrate 7, the light-emitting device is taller by the thickness of the metal members 14, and portions of each first metal member 14 with and without the cladding 11 are to have different thermal contraction rates. Such a difference in thermal contraction may cause deformation of the entire module, separation between the cladding 11 and the first metal members 14 or between the first metal members 14 and the substrate 7, or cracks in the cladding 11. When the first metal members 14 are located in the openings alone, the light-emitting device is less tall and may be less susceptible to thermal contraction.

### Fourth Embodiment

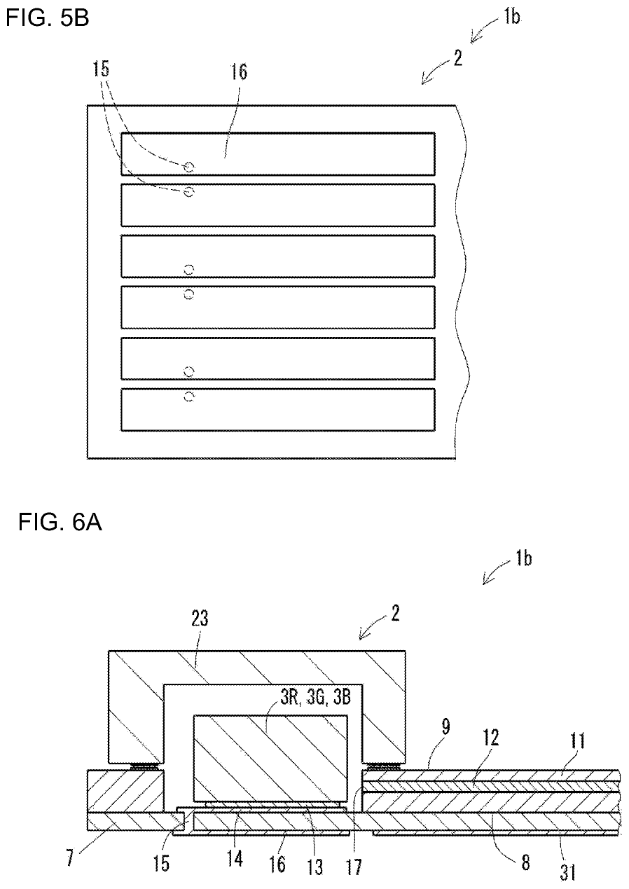

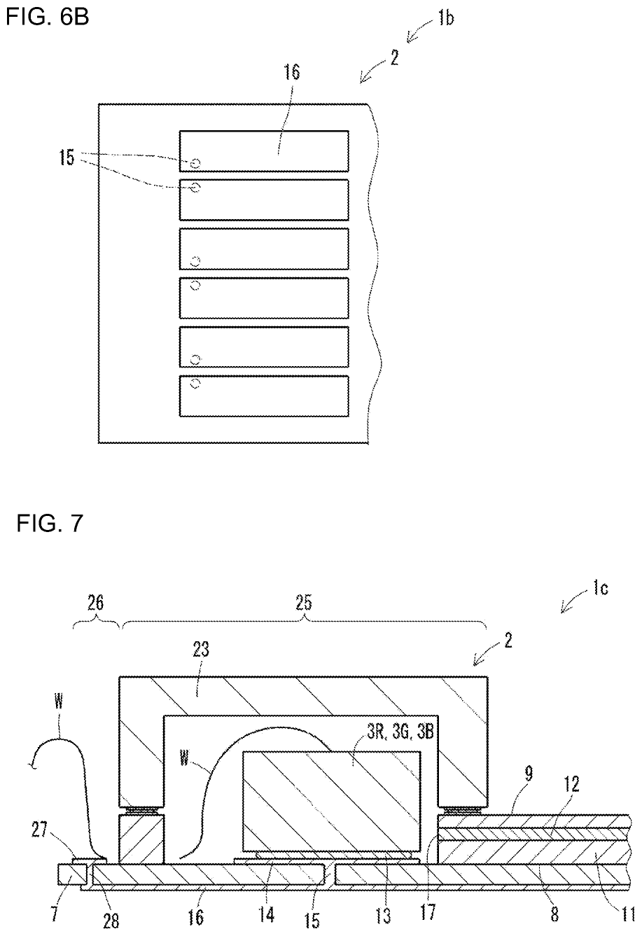

FIG. 5A is a cross-sectional view of a light-emitting device 1b according to a fourth embodiment. FIG. 5B is a bottom view of the light-emitting device 1b. FIG. 6A is a cross-sectional view of a light-emitting device 1b with an example structure similar to the structure according to the fourth embodiment. FIG. 6B is a bottom view of the light-emitting device 1b. The same reference numerals denote the components corresponding to those in the above embodiments and will not be described repeatedly. In the light-emitting device 1b according to the present embodiment, second metal members 16 are larger than the first metal members 14 in a transparent bottom view as viewed through in a direction toward the fourth surface 9. In the present embodiment, the second metal members 16 are elongated in the longitudinal direction of the substrate 7 (the lateral direction in FIGS. 5A, 5B, 6A, and 6B). The second metal members 16 being longer and thus larger than the first metal members 14 simplifies secondary mounting to an external circuit and improves heat dissipation.

### Fifth Embodiment

FIG. 7 is a partial cross-sectional view of a light-emitting device 1c according to a fifth embodiment. The same reference numerals denote the components corresponding to those in the above embodiments and will not be described repeatedly. In the light-emitting device 1c according to the present embodiment, the second surface 6 includes a third area 25 inward from the outer periphery of the cladding 11 and a fourth area 26 other than the third area 25. Third metal members 27 are located in the fourth area 26. Each third metal member 27 is connected to the corresponding second metal member 16 with a second via conductor 28 extending through the substrate 7 from the first surface 5 to the second surface 6 of the substrate 7.

This structure allows formation of lead electrodes on the surface without separating the lid 23 and the cladding 11. The third metal members 27 on the external fourth area 26 may be easily connected to an external power supply with the wiring members W.

### Sixth Embodiment

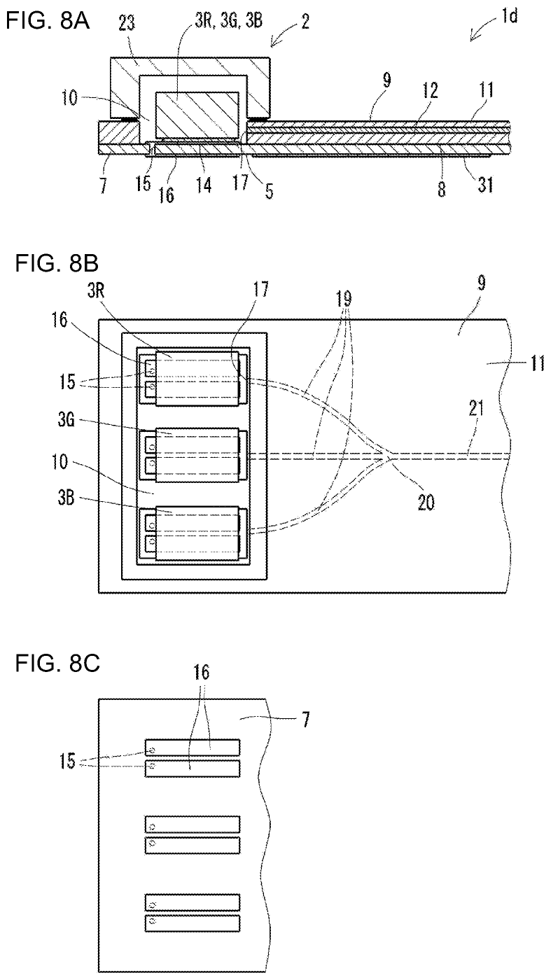

FIG. 8A is a cross-sectional view of a light-emitting device 1d according to a sixth embodiment. FIG. 8B is a plan view of the light-emitting device 1d without the lid 23. FIG. 8C is a bottom view of the light-emitting device 1d. The same reference numerals denote the components corresponding to those in the above embodiments and will not be described repeatedly. In the light-emitting device 1d according to the present embodiment, first metal members 14 and second metal members 16 have the same shape and are plane symmetrical with respect to a plane parallel to the first surface 5. This structure has higher symmetry in the vertical direction in FIG. 8A in a side view and reduces deformation directly below the element mounts 13.

### Seventh Embodiment

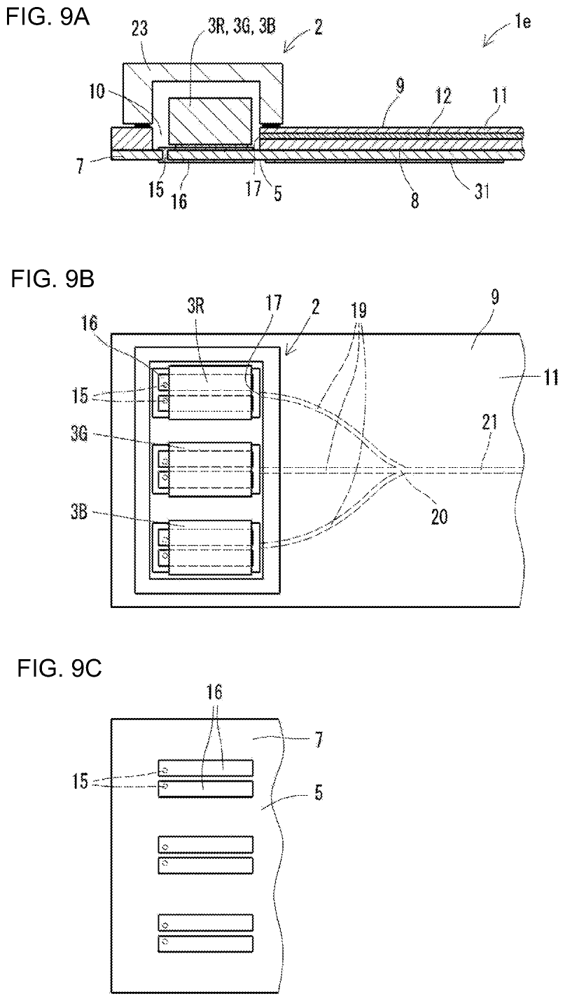

FIG. 9A is a cross-sectional view of a light-emitting device 1e according to a seventh embodiment. FIG. 9B is a plan view of the light-emitting device 1e without the lid 23. FIG. 9C is a bottom view of the light-emitting device 1e. The same reference numerals denote the components corresponding to those in the above embodiments and will not be described repeatedly. In the light-emitting device 1e according to the present embodiment, second metal members 16 located on the first surface 5 include surfaces opposite to their surfaces facing the first surface 5 that are flat, or in other words, form a flat surface. This structure reduces tilt during secondary mounting, allows mounting of the light-emitting device le in a leveler state, and stabilizes secondary mounting to an external circuit.

### Eighth Embodiment

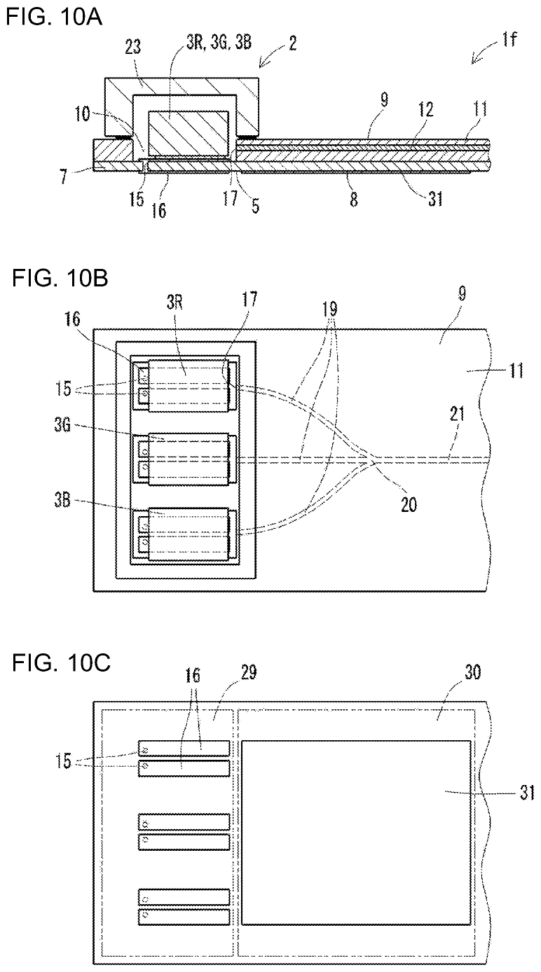

FIG. 10A is a cross-sectional view of a light-emitting device 1f according to an eighth embodiment. FIG. 10B is a plan view of the light-emitting device 1f without the lid 23. FIG. 10C is a bottom view of the light-emitting device 1f. The same reference numerals denote the components corresponding to those in the above embodiments and will not be described repeatedly. In the light-emitting device 1f according to the present embodiment, second metal members 16 located on the first surface 5 include surfaces opposite to their surfaces facing the first surface 5 that are flat, or in other words, form a flat surface. The first surface 5 includes a fifth area 29 in which the second metal members 16 are located and a sixth area 30 other than the fifth area 29. A fourth metal member 31 is located on the sixth area 30. The fourth metal member 31 includes a surface opposite to its surface facing the first surface 5 that is flat similarly to the second metal members 16, or in other words, is formed on a common flat surface including the surfaces of the second metal members 16. This structure simplifies the manufacturing processes by allowing formation of the second metal members 16 and the fourth metal member 31 at the same time, and improves heat dissipation.

### Ninth Embodiment

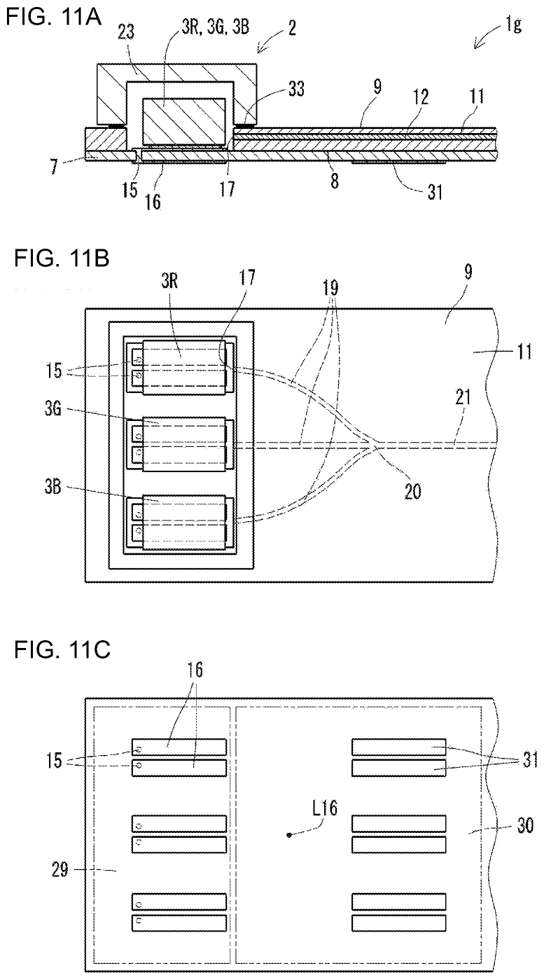

FIG. 11A is a cross-sectional view of a light-emitting device 1g according to a ninth embodiment. FIG. 11B is a plan view of the light-emitting device 1g without the lid 23. FIG. 11C is a bottom view of the light-emitting device 1g. The same reference numerals denote the components corresponding to those in the above embodiments and will not be described repeatedly. In the light-emitting device 1g according to the present embodiment, the second metal members 16 are located on the first surface 5. The first surface 5 includes the fifth area 29 in which the second metal members 16 are located and the sixth area 30 other than the fifth area 29. Fourth metal members 31 are located in the sixth area 30. The second metal members 16 and the fourth metal members 31 are line symmetrical with respect to a central line L1 including the center of the first surface 5. This structure reduces asymmetric distribution of deformation with respect to the central line L1 due to higher temperatures of the second metal members 16 and the fourth metal members 31, and thus generates less thermal stress.

### Tenth Embodiment

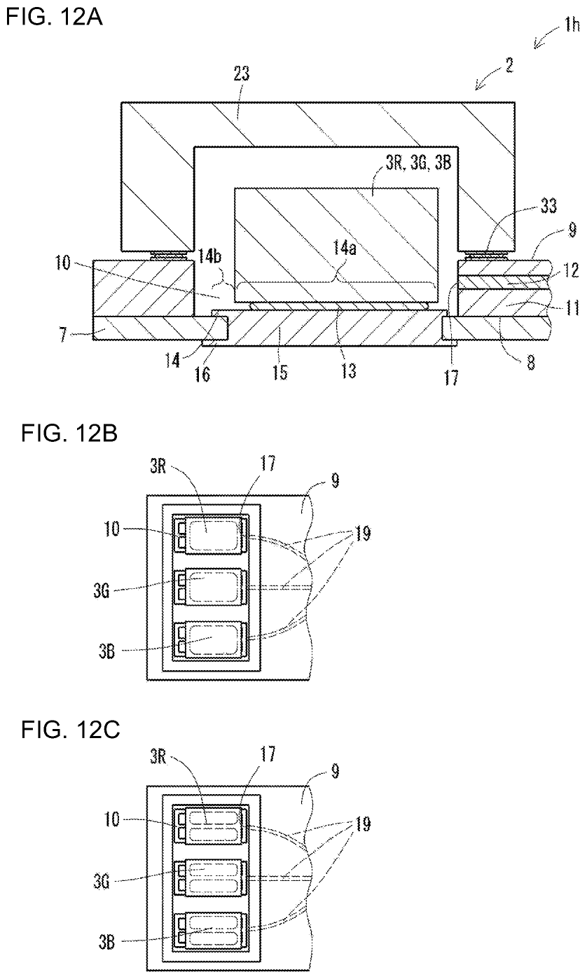

FIG. 12A is a cross-sectional view of a light-emitting device 1h according to a tenth embodiment. FIG. 12B is a plan view of the light-emitting device 1h without the lid 23. FIG. 12C is a bottom view of the light-emitting device 1h. The same reference numerals denote the components corresponding to those in the above embodiments and will not be described repeatedly. In the light-emitting device 1h according to the present embodiment, a contact area between each first via conductor 15 and the first metal member 14 is larger than or as large as the corresponding first area 14a. This structure increases the efficiency of heat transfer from the first metal members 14 located inside to the corresponding second metal members 16 located outside, and improves heat dissipation.

### Eleventh Embodiment

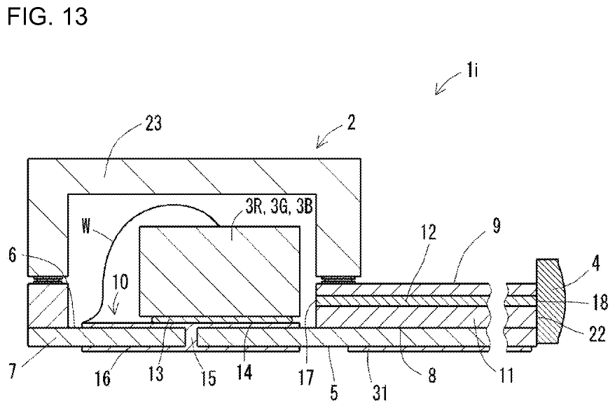

FIG. 13 is a cross-sectional view of a light-emitting device 1i according to an eleventh embodiment. The same reference numerals denote the components corresponding to those in the above embodiments and will not be described repeatedly. In the present embodiment, the light-emitting device 1i includes the lid 23 sealing the element-receiving portion 10. The lid 23 can prevent unintended entry of external light through the incident end faces 17 of the core 12. With entry of unintended water and gas also being less likely, the light-emitting elements 3R, 3G, and 3B are less likely to corrode and thus can have longer service lives. The lid 23 with airtight sealing is particularly effective. With the lid 23 sealing the element-receiving portion 10, foreign matter such as objects suspended in the air are less likely to enter the element-receiving portion 10. This reduces objects that block traveling light in a space between the emission end of each light-emitting element 3R, 3G, or 3B and the corresponding incident end face 17 of the core 12.

### Twelfth Embodiment

In another example similar to the eleventh embodiment, a light-emitting device 1i includes a metal layer 33, which is, for example, a soldered bonding layer made of AuSn, SnAgCu, or another material, between the element-receiving portion 10 and the lid 23. The metal layer 33 airtightly joins the lid 23 and the cladding 11 together to seal the element-receiving portion 10 as described above.

In still another embodiment of the present disclosure, the light-emitting elements 3R, 3G, and 3B are not limited to light-emitting diodes (LEDs) but may be, for example, laser diodes (LDs) or vertical-cavity surface-emitting lasers (VCSELs).

The present disclosure may be implemented in the following forms.

In one or more embodiments of the present disclosure, an optical waveguide package includes a substrate including a first surface and a second surface opposite to the first surface, a cladding located on the second surface and including a third surface facing the second surface, a fourth surface opposite to the third surface, and an element-receiving portion with an opening in the fourth surface, a core located in the cladding and extending from the element-receiving portion, and a first metal member located in the element-receiving portion in a plan view as viewed in a direction toward the fourth surface and including an element mount. The first metal member is connected to a second metal member with a first via conductor extending through the substrate from the first surface to the second surface.

In one or more embodiments of the present disclosure, a light-emitting device includes the optical waveguide package according to the above embodiments, a light-emitting element connected to the first metal member, and a lens on an optical path of light emitted from the core.

In one or more embodiments of the present disclosure, the optical waveguide package includes a simple connection structure to achieve high insulation at a low manufacturing cost.

In one or more embodiments of the present disclosure, the light-emitting device includes a simple connection structure to achieve high insulation at a low manufacturing cost.

Although embodiments of the present disclosure have been described in detail, the present disclosure is not limited to the embodiments described above, and may be changed or varied in various manners without departing from the spirit and scope of the present disclosure. The components described in the above embodiments may be entirely or partially combined as appropriate unless any contradiction arises.

### REFERENCE SIGNS

1, 1a to 1i light-emitting device

2 optical waveguide package

3R, 3G, 3B light-emitting element

4 condenser lens

5 first surface

6 second surface

7 substrate

8 third surface

9 fourth surface

10 element-receiving portion

11 cladding

12 core

13 element mount

14 first metal member

15 first via conductor

16 second metal member

17 incident end face

18 emission end face

19 branching path

20 merging portion

21 joined path

22 side surface

23 lid

25 third area

26 fourth area

27 third metal member

28 second via conductor

29 fifth area

30 sixth area

31 fourth metal member

33 metal layer

1. An optical waveguide package, comprising:
a substrate including a first surface and a second surface opposite to the first surface;
a cladding on the second surface, the cladding including a third surface facing the second surface, a fourth surface opposite to the third surface, and an element-receiving portion with an opening in the fourth surface;
a core in the cladding, the core extending from the element-receiving portion; and
a first metal member in the element-receiving portion in a plan view as viewed in a direction toward the fourth surface, the first metal member including an element mount,
wherein the first metal member is connected to a second metal member with a first via conductor extending through the substrate from the first surface to the second surface.

2. The optical waveguide package according to claim 1, wherein the element-receiving portion extends from the fourth surface to the third surface.

3. The optical waveguide package according to claim 1, wherein
the first metal member includes a first area being the element mount and a second area other than the first area, and
the first via conductor is in contact with the second area.

4. The optical waveguide package according to claim 1, wherein
the first metal member is located in the opening alone in the plan view.

5. The optical waveguide package according to claim 1, wherein
the second metal member is larger than the first metal member in a transparent plan view as viewed through in a direction toward the fourth surface.

6. The optical waveguide package according to claim 5, wherein
the second surface includes a third area inward from an outer periphery of the cladding and a fourth area other than the third area,
the optical waveguide package further includes a third metal member located in the fourth area, and
the third metal member is connected to the second metal member with a second via conductor extending through the substrate from the first surface to the second surface.

7. The optical waveguide package according to claim 1, wherein
the first metal member and the second metal member have a same shape and are plane symmetrical with respect to the first surface.

8. The optical waveguide package according to claim 1, wherein
the second metal member is on the first surface, and the second metal member includes a flat surface opposite to a surface facing the first surface.

9. The optical waveguide package according to claim 1, wherein
the second metal member is on the first surface, and the second metal member includes a surface opposite to a flat surface facing the first surface,
the first surface includes a fifth area in which the second metal member is located and a sixth area other than the fifth area,
the optical waveguide package further includes a fourth metal member in the sixth area, and
the fourth metal member includes, similarly to the second metal member, a flat surface opposite to a surface facing the first surface.

10. The optical waveguide package according to claim 1, wherein
the second metal member is on the first surface,
the first surface includes a fifth area in which the second metal member is located and a sixth area other than the fifth area,
the optical waveguide package further includes a fourth metal member in the sixthfourth area, and
the second metal member and the fourth metal member are line symmetrical with respect to a central line including a center of the first surface.

11. The optical waveguide package according to claim 3, wherein
a contact area between the first via conductor and the first metal member is larger than or as large as the first area.

12. The optical waveguide package according to claim 1, further comprising:
a lid sealing the element-receiving portion.

13. The optical waveguide package according to claim 12, further comprising:
a metal layer between the element-receiving portion and the lid.

14. A light-emitting device, comprising:
the optical waveguide package according to claim 1;
a light-emitting element connected to the first metal member; and
a lens on an optical path of light emitted from the core.

15. The light-emitting device according to claim 14, wherein the lid includes a recess, and
the light-emitting element extends from the element-receiving portion into the recess.
